(19) United States
(12) Patent Application Publication
(10) Pub. No.: US 2024/0188389 A1
(43) Pub. Date: Jun. 6, 2024

(54) DISPLAY APPARATUS, AND DISPLAY PANEL AND MANUFACTURING METHOD THEREFOR

(71) Applicants: Chengdu BOE Optoelectronics Technology Co., Ltd., Chendu, Sichuan (CN); BOE Technology Group Co., Ltd., Beijing (CN)

(72) Inventors: Jiang LIU, Beijing (CN); Dawei WANG, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/279,398

(22) PCT Filed: Nov. 17, 2021
(86) PCT No.: PCT/CN2021/131322

§ 371 Date: Aug. 30, 2023

(30) Foreign Application Priority Data
Mar. 25, 2021 (CN) 202110321693.4

(51) Int. Cl. H10K 59/80; H10K 59/12; H10K 59/122

(52) U.S. Cl. CPC H10K 59/8731; H10K 59/1201; H10K 59/122

(57) ABSTRACT

A display apparatus, and a display panel and a manufacturing method therefor. The display panel includes a substrate, a driving device layer, a planarization layer, a light emitting layer, a blocking dam, a first inorganic encapsulation layer, an organic encapsulation layer and a second an organic encapsulation layer. The organic encapsulation layer is arranged on a surface of the first inorganic encapsulation layer away from the substrate, and an orthographic projection of the planarization layer on the substrate is located within an orthographic projection of the organic encapsulation layer on the substrate.

### CROSS-REFERENCE TO RELATED APPLICATION(S)

This application claims priority to Chinese patent application No. 202110321693.4, entitled “DISPLAY APPARATUS, DISPLAY PANEL AND MANUFACTURING METHOD THEREOF” and filed on Mar. 25, 2021, the entire content of which is incorporated herein by reference in its entirety.

### TECHNICAL FIELD

The present disclosure relates to the display technical field, and in particular, to a display device, a display panel and a method for manufacturing the display panel.

### BACKGROUND

At present, display panels have been widely used in various electronic devices. The encapsulation process is an important process to improve reliability, especially for organic electroluminescent display panels. An encapsulation layer is usually needed to avoid erosion of light emitting devices and circuits by external water and oxygen. However, in the existing display panels, when other film layers after the encapsulation layer are formed, the quality of film formation is prone to problems, and it is difficult to form predetermined patterns.

It should be noted that the information disclosed in the background section above is only used to enhance the understanding of the background of the present disclosure, and therefore may include information that does not constitute the prior art known to those skilled in the art.

### SUMMARY

The present disclosure provides a display device, a display panel and a method for manufacturing the display panel.

According to an aspect of the present disclosure, there is provided a display panel, including:
a substrate including a display area and a peripheral area outside the display area, wherein the peripheral area includes a circuit area and a blocking area sequentially distributed along a direction away from the display area;
a driving device layer arranged on a side of the substrate and covering the display area and the peripheral area;
a planarization layer arranged on a side of the driving device layer away from the substrate, wherein a boundary of an orthographic projection of the planarization layer on the substrate is located within the circuit area;
a light emitting layer arranged on a surface of the planarization layer away from the substrate, wherein an orthographic projection of the light emitting layer on the substrate at least covers the display area;
a blocking dam arranged on a side of the driving device layer away from the substrate and arranged around the display area, wherein an orthographic projection of the blocking dam on the substrate is located in the blocking area;
a first inorganic encapsulation layer covering the light emitting layer and the blocking dam, wherein an orthographic projection of the first inorganic encapsulation layer on the substrate covers the display area and the peripheral area;
an organic encapsulation layer arranged on a surface of the first inorganic encapsulation layer away from the substrate, wherein an orthographic projection of the planarization layer on the substrate is located within an orthographic projection of the organic encapsulation layer on the substrate; and
a second inorganic encapsulation layer covering the organic encapsulation layer, wherein an orthographic projection of the second inorganic encapsulation layer on the substrate covers the display area and the peripheral area.

In an example embodiment of the present disclosure, the planarization layer includes:
a first planarization layer covering the driving device layer, wherein a boundary of an orthographic projection of the first planarization layer on the substrate is located within the circuit area; and
a second planarization layer arranged on a side of the first planarization layer away from the substrate, wherein a boundary of an orthographic projection of the second planarization layer on the substrate is located within the circuit area, and the light emitting layer is arranged on a surface of the second planarization layer away from the substrate.

In an example embodiment of the present disclosure, the light emitting layer includes:
a first electrode layer arranged on the side of the second planarization layer away from the substrate, wherein the first electrode layer includes a first electrode and an interconnection portion, an orthographic projection of the first electrode on the substrate is located in the display area, and an orthographic projection of the interconnection portion on the substrate is located in the circuit area;
a pixel definition layer arranged on a surface of the second planarization layer away from the substrate, wherein an orthographic projection of the pixel definition layer on the substrate covers the display area and the circuit area, and the pixel definition layer is provided with a pixel opening exposing the first electrode and an interconnection opening exposing the interconnection portion;
a light emitting functional layer covering the pixel definition layer and the first electrode, wherein an orthographic projection of the light emitting functional layer on the substrate is located in the display area; and
a second electrode layer covering the light emitting functional layer, wherein a boundary of an orthographic projection of the second electrode layer on the substrate is located in the circuit area, and the second electrode layer is connected to the interconnection portion through the interconnection opening;
wherein the first inorganic encapsulation layer covers the second electrode layer.

In an example embodiment of the present disclosure, the blocking dam includes a first dam and a second dam, and the second dam surrounds the first dam.

In an example embodiment of the present disclosure, the first dam is arranged in the same layer as the pixel definition layer, the second dam includes a first blocking layer and a second blocking layer stacked in a direction away from the substrate, the first blocking layer is arranged in the same layer as the second planarization layer, and the second blocking layer is arranged in the same layer as the pixel definition layer.

In an example embodiment of the present disclosure, the first electrode layer further includes:
an extension portion connected to the interconnection portion, wherein an orthographic projection of the extension portion on the substrate is located in the blocking area;
wherein the first dam is arranged on a surface of the extension portion away from the substrate.

In an example embodiment of the present disclosure, the driving device layer includes:
an active layer arranged on a side of the substrate, wherein an orthographic projection of the active layer on the substrate is located in the display area and the circuit area;
a first gate insulating layer covering the active layer and the substrate;
a gate arranged on a surface of the first gate insulating layer away from the substrate, wherein an orthographic projection of the gate on the substrate is located in the display area and the circuit area;
a second gate insulating layer covering the gate and the first gate insulating layer;
an interlayer dielectric layer covering the second gate insulating layer;
an source and drain layer arranged on a surface of the interlayer dielectric layer away from the substrate, wherein an orthographic projection of the source and drain layer on the substrate is located in the display area and the circuit area; and
the first planarization layer arranged on a side of the source and drain layer away from the substrate;
wherein the display panel further includes:
a connection layer arranged on a surface of the first planarization layer away from the substrate and connected to the source and drain layer, wherein an orthographic projection of the connection layer on the substrate is located in the display area;
a signal line arranged on a side of the blocking dam close to the substrate, wherein the signal line includes a first line layer and a second line layer stacked sequentially in a direction away from the substrate, the first line layer is arranged in the same layer as the source and drain layer, the second line layer is arranged in the same layer as the connection layer, and at least a partial area of the second dam is arranged on a surface of the second line layer away from the substrate;
wherein the extension portion is arranged on a surface of the signal line away from the substrate.

In an example embodiment of the present disclosure, the second planarization layer is provided with a first blocking groove penetrating through the second planarization layer and the first planarization layer, and an orthographic projection of the first blocking groove on the substrate is located in the circuit area and surrounds the display area.

In an example embodiment of the present disclosure, the interlayer dielectric layer is provided with a second blocking groove, and an orthographic projection of the second blocking groove on the substrate surrounds the second dam.

In an example embodiment of the present disclosure, a distance between a boundary of the second planarization layer and the first dam is a first distance, and a distance between a boundary of the second planarization layer and the second dam is a second distance; and
a ratio of the second distance to the first distance is 7/5.

According to another aspect of the present disclosure, there is provided a method for manufacturing a display panel, including:
providing a substrate, wherein the substrate includes a display area and a peripheral area outside the display area, and the peripheral area includes a circuit area and a blocking area sequentially distributed along a direction away from the display area;
forming a driving device layer covering the display area and the peripheral area on a side of the substrate;
forming a planarization layer on a side of the driving device layer away from the substrate, wherein a boundary of an orthographic projection of the planarization layer on the substrate is located within the circuit area;
forming a blocking dam on a side of the driving device layer away from the substrate, wherein the blocking dam is arranged around the display area, and an orthographic projection of the blocking dam on the substrate is located in the blocking area;
forming a light emitting layer on a surface of the planarization layer away from the substrate, wherein an orthographic projection of the light emitting layer on the substrate at least covers the display area;
forming a first inorganic encapsulation layer covering the light emitting layer and the blocking dam, wherein an orthographic projection of the first inorganic encapsulation layer on the substrate covers the display area and the peripheral area;
forming a liquid organic material layer on a surface of the first inorganic encapsulation layer away from the substrate, wherein:
an orthographic projection of the organic material layer on the substrate is located within a range surrounded by the blocking dam, and there is a gap between the organic material layer and the blocking dam;
a boundary of the orthographic projection of the planarization layer on the substrate is located within the orthographic projection of the organic material layer on the substrate, and at least partially overlaps with a boundary of the orthographic projection of the organic material layer on the substrate;
after the organic material layer is leveled to form an organic encapsulation layer, forming a second inorganic encapsulation layer covering the organic material layer, wherein an orthographic projection of the second inorganic encapsulation layer on the substrate covers the display area and the peripheral area.

In an example embodiment of the present disclosure, forming the planarization layer on the side of the driving device layer away from the substrate includes:
forming a first planarization layer covering the driving device layer, wherein a boundary of an orthographic projection of the first planarization layer on the substrate is located in the circuit area; and
forming a second planarization layer on a side of the first planarization layer away from the substrate, wherein a boundary of an orthographic projection of the second planarization layer on the substrate is located in the circuit area;
wherein the light emitting layer is arranged on a surface of the second planarization layer away from the substrate.

In an example embodiment of the present disclosure, each of the orthographic projections of the second planarization layer and the organic material layer on the substrate is a rectangle, and two adjacent sides of the rectangle are connected through a rounded corner;
a rounded corner of the orthographic projection of the second planarization layer on the substrate is inscribed in a rounded corner of the orthographic projection of the organic material layer on the substrate.

In an example embodiment of the present disclosure, forming the light emitting layer on the surface of the second planarization layer away from the substrate; including:
forming a first electrode layer on a side of the second planarization layer away from the substrate, wherein the first electrode layer includes a first electrode and an interconnection portion, an orthographic projection of the first electrode on the substrate is located in the display area, and an orthographic projection of the interconnection portion on the substrate is located in the circuit area;
forming a pixel definition layer on the surface of the second planarization layer away from the substrate, wherein an orthographic projection of the pixel definition layer on the substrate covers the display area and the circuit area, and the pixel definition layer is provided with a pixel opening exposing the first electrode and an interconnection opening exposing the interconnection portion;
forming a light emitting functional layer covering the pixel definition layer and the first electrode, wherein an orthographic projection of the light emitting functional layer on the substrate is located within the display area;
forming a second electrode layer covering the light emitting functional layer, wherein a boundary of an orthographic projection of the second electrode layer on the substrate is located in the circuit area, and the second electrode layer is connected to the interconnection portion through the interconnection opening;
wherein:
the blocking dam includes a first dam and a second dam, and the second dam surrounds the first dam;
the second dam includes a first blocking layer and a second blocking layer stacked in a direction away from the substrate, the first blocking layer and the second planarization layer are provided simultaneously through one patterning process, and the second blocking layer, the first dam and the pixel definition layer are simultaneously formed through one patterning process.

In an example embodiment of the present disclosure, a thickness of the first dam is not greater than 2 μm, and a thickness of the organic material layer is not less than 8 μm.

According to another aspect of the present disclosure, there is provided a display device, including the display panel according to any one of above embodiments.

It is to be understood that both the foregoing general description and the following detailed description are exemplary and explanatory only and are not restrictive of the present disclosure.

### BRIEF DESCRIPTION OF THE DRAWINGS

The accompanying drawings, which are incorporated in and constitute a part of the specification, illustrate embodiments consistent with the present disclosure and together with the specification serve to explain the principles of the present disclosure. Apparently, the drawings in the following description are only some embodiments of the present disclosure, and those skilled in the art may obtain other drawings according to these drawings without creative efforts.

FIG. 1 is a top view of an embodiment of a display panel of the present disclosure.

FIG. 2 is an A-A sectional view of FIG. 1.

FIG. 3 is a B-B sectional view of FIG. 1.

FIG. 4 is a flowchart of a manufacturing method according to an embodiment of the present disclosure.

FIG. 5 is a schematic diagram of boundaries in a display panel of the present disclosure.

### REFERENCE SIGNS

1: substrate; 101: display area; 102: peripheral area; 1021: circuit area; 1022: blocking area;
2: driving device layer; 21: active layer; 22: first gate insulating layer; 23: gate; 24: second gate insulating layer; 25: interlayer dielectric layer; 251: second blocking groove; 26: source and drain layer; 261: source; 262: drain;
100: planarization layer; 3: first planarization layer; 31: first blocking groove; 4: second planarization layer;
5: light emitting layer; 51: first electrode layer; 511: first electrode; 512: interconnection portion; 513: extension portion; 52: pixel definition layer; 521: pixel opening; 522: interconnection opening; 53: light emitting function layer; 54: second electrode layer;
6: blocking dam; 61: first dam; 62: second dam; 621: first blocking layer; 622: second blocking layer;
7: first inorganic encapsulation layer;
8: organic encapsulation layer;
9: second inorganic encapsulation layer;
10: connection layer;
11: signal line; 111: first line layer; 112: second line layer;
001: first boundary; 002: second boundary; 003: third boundary.

### DETAILED DESCRIPTION

Example implementations will now be described more fully with reference to the accompanying drawings. Example implementations can, however, be embodied in many forms and should not be construed as being limited to the implementations set forth herein; rather, these implementations are provided so that the present disclosure will be thorough and complete, and will fully convey the concept of example implementations to those skilled in the art. The same reference numerals in the drawings denote the same or similar structures, and thus their detailed descriptions will be omitted. Furthermore, the drawings are merely schematic illustrations of the present disclosure and are not necessarily drawn to scale.

Although relative terms such as “upper” and “lower” are used in this specification to describe a relative relationship of one component shown with respect to another component, these terms are used in this specification only for convenience. For example, descriptions are made according to the directions shown in the accompanying drawings. It will be appreciated that if an illustrated device is turned over so that it is upside down, then an element described as being “upper” will become an element being “lower”. When a structure is “on” another structure, it may mean that the structure is integrally formed on another structure, or that the structure is “directly” arranged on another structure, or that the structure is “indirectly” arranged on another structure through other structures.

The terms “one”, “a/an”, “the”, “said” and “at least one” are used to indicate the presence of one or more elements/components/etc.; the terms “comprising/comprises/comprise” and “having/has/have” are used to indicate an open-ended inclusive, and means that there may be additional elements/components/etc. in addition to the listed elements/components/etc. The words “first” and “second” are used as markers only, but are not used to limit the number of objects.

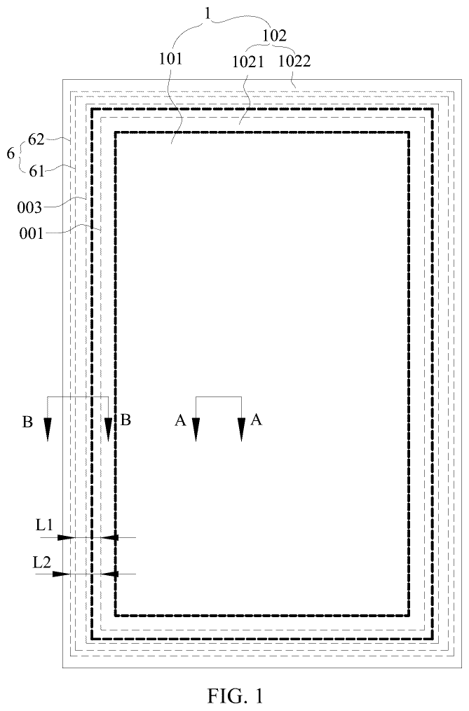

An embodiment of the present disclosure provides a display panel, which may be an organic light emitting diode (OLED) display panel. As shown in FIGS. 1 to 3, the display panel of the present disclosure may include a substrate 1, a driving device layer 2, a planarization layer 100, a light emitting layer 5, a blocking dam 6, a first inorganic encapsulation layer 7, an organic encapsulation layer 8 and a second inorganic encapsulation layer 9.

The substrate 1 includes a display area 101 and a peripheral area 102 which is located outside the display area 101. The peripheral area 102 includes a circuit area 1021 and a blocking area 1022 distributed sequentially along a direction away from the display area 101.

The driving device layer 2 is arranged on a side of the substrate 1 and covers the display area 101 and the peripheral area 102.

The planarization layer 100 is arranged on a side of the driving device layer 2 away from the substrate 1, and a boundary of an orthographic projection of the planarization layer 100 on the substrate 1 is located in the circuit area 1021.

The light emitting layer 5 is arranged on a surface of a second planarization layer 4 away from the substrate 1, and an orthographic projection of the light emitting layer 5 on the substrate 1 at least covers the display area 101.

The blocking dam 6 is arranged on a side of the driving device layer 2 away from the substrate 1, and is arranged around the display area 101, and an orthographic projection of the blocking dam 6 on the substrate 1 is located in the blocking area 1022.

The first inorganic encapsulation layer 7 covers the light emitting layer 5 and the blocking dam 6, and an orthographic projection of the first inorganic encapsulation layer 7 on the substrate 1 covers the display area 101 and the peripheral area 102.

The organic encapsulation layer 8 is arranged on a surface of the first inorganic encapsulation layer 7 away from the substrate 1, an orthographic projection of the organic encapsulation layer 8 on the substrate 1 is located within a range surrounded by the blocking dam 6, and an orthographic projection of the second planarization layer 4 on the substrate 1 is located within the orthographic projection of the organic encapsulation layer 8 on the substrate 1.

The second inorganic encapsulation layer 9 covers the organic encapsulation layer 8, and the orthographic projection of the second inorganic encapsulation layer 9 on the substrate 1 covers the display area 101 and the peripheral area 102.

The display panel of the embodiment of the present disclosure can protect the light emitting layer 5 through the first inorganic encapsulation layer 7, the organic encapsulation layer 8 and the second inorganic encapsulation layer 9. Specifically, the first inorganic encapsulation layer 7 and the second inorganic encapsulation layer 9 can block water and oxygen to prevent erosion. The organic encapsulation layer 8 can realize planarization and buffering. When forming the organic encapsulation layer 8, a liquid organic material layer can be formed, and the boundary of the planarization layer 100 (that is, a first boundary 001) can be located within the boundary of the organic material layer (that is, within the second boundary 002). After the organic material layer is leveled to form the organic encapsulation layer 8, it can be ensured that the boundary of the planarization layer 100 (that is, the third boundary 003) is located within the boundary of the organic encapsulation layer 8. Since the first boundary 001 is located in the circuit area 1021 and does not extend to the boundary of the substrate 1, a step is formed, and the organic encapsulation layer 8 can realize planarization at the position of the step, avoiding occurrence of accumulation of photoresist at outer side of the step in a subsequent process; accumulated photoresist is difficult to sufficiently expose in the exposure process and may affect the formation of subsequent film layers such as a touch layer and thereby affect product quality. For example, when the touch layer is formed on the second inorganic encapsulation layer, a plurality of traces are arranged on the edge of the touch layer, and in at least a part of the traces, at least partial area of each trace is outside the boundary of the planarization layer. There is a height difference at the boundary, and thus the photoresist is easy to accumulate, and it is difficult to completely separate areas of two adjacent traces located outside the boundary, and as a result a short circuit occurs.

The display panel of the present disclosure will be described in detail below.

As shown in FIGS. 1 to 3, the substrate 1 may include a display area 101 and a peripheral area 102. The peripheral area 102 is located outside the display area 101. For example, the peripheral area 102 is an annular area surrounding the display area 101. Meanwhile, the peripheral area 102 may include a circuit area 1021 and a blocking area 1022 sequentially distributed along a direction away from the display area 101. The substrate 1 may be a single-layer or multi-layer structure, and its material may include a hard material such as glass, or a flexible material such as polyimide.

As shown in FIGS. 1 to 3, the driving device layer 2 is arranged on a side of the substrate 1 and covers the display area 101 and the peripheral area 102. That is, the driving device layer 2 covers the display area 101, the circuit area 1021 and the blocking area 1022. The driving device layer 2 is used to set driving devices required by the driving circuit, and the driving devices may include thin film transistors and capacitors, etc. The area of the driving device layer 2 corresponding to the display area 101 may be provided with thin film transistors and capacitors required for the pixel circuits. The area of the driving device layer 2 corresponding to the circuit area 1021 may be provided with thin film transistors and capacitors required for peripheral circuits, and the peripheral circuits may include gate driving circuits and may further include light emitting control circuits.

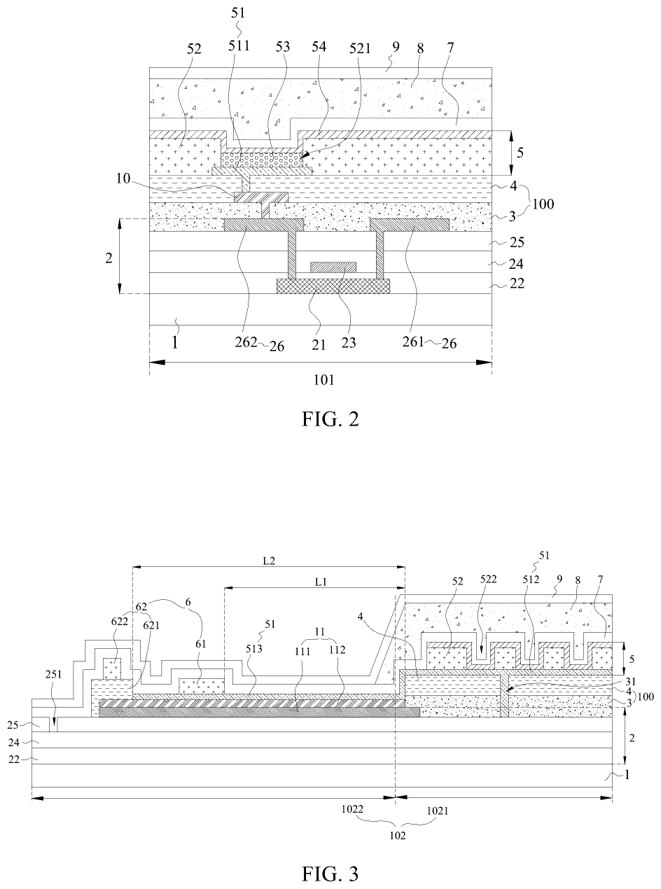

In some embodiments of the present disclosure, as shown in FIG. 2, taking a top-gate thin film transistor as an example, it may include an active layer 21, a first gate insulating layer 22, a gate 23, a second gate insulating layer 24, an interlayer dielectric layer 25 and a source and drain layer 26 which are stacked in a direction away from the substrate 1. The driving device layer 2 has a plurality of thin film transistors, and the same film layers of any two thin film transistors in at least a part of the thin film transistors may be arranged in the same layer, and thus the film layer structure of the driving device layer 2 may be described by describing the structure of a thin film transistor. That is, the driving device layer 2 may include an active layer 21, a first gate insulating layer 22, a gate 23, a second gate insulating layer 24, an interlayer dielectric layer 25 and a source and drain layer 26.

The active layer 21 is arranged on a side of the substrate 1. Since each thin film transistor has an active layer 21, there are multiple active layers 21, and the orthographic projections of the active layers 21 on the substrate 1 are located in the display area 101 and the circuit area 1021, that is, the display area 101 and the circuit area 1021 are both provided with active layers 21.

The first gate insulating layer 22 covers the active layer 21 and the substrate 1, and the first gate insulating layer 22 may cover the display area 101, the circuit area 1021 and the blocking area 1022.

The gate 23 is arranged on a surface of the first gate insulating layer 22 away from the substrate 1. Since each thin film transistor has a gate 23, there are multiple gates 23, and the gates 23 are distributed in the display area 101 and the circuit area 1021, that is, the orthographic projections of the gates 23 on the substrate 1 are located in the display area 101 and the circuit area 1021. Meanwhile, the gates 23 and the active layers 21 are arranged in one-to-one correspondence in a direction perpendicular to the substrate 1, that is, the orthographic projection of a gate 23 on the substrate 1 at least partially overlaps with a corresponding active layer 21.

The second gate insulating layer 24 covers the gate 23 and the first gate insulating layer 22, and the boundary of the second gate insulating layer 24 may be flush with the boundary of the first gate insulating layer 22.

The interlayer dielectric layer 25 may cover the second gate insulating layer 24 and may be flush with the boundary of the second gate insulating layer 24. That is, the orthographic projection of the interlayer dielectric layer 25 on the substrate 1 covers the display area 101 and the peripheral area 102. The material of the interlayer dielectric layer 25 may be an organic material. In order to prevent external water and oxygen from intruding into the display area 101 along the interlayer dielectric layer 25, the interlayer dielectric layer 25 may be provided with a second blocking groove 251 penetrating the interlayer dielectric layer 25 along a direction perpendicular to the substrate 1. The second blocking groove 251 is an annular groove surrounding the circuit area 1021, so as to cut off the path of water and oxygen intruding into the display area 101 along the interlayer dielectric layer 25.

The source and drain layer 26 is arranged on a surface of the interlayer dielectric layer 25 away from the substrate 1. Since each thin film transistor has a source and drain layer 26, there are multiple source and drain layers 26, and the source and drain layers 26 are distributed in the display area 101 and the circuit area 1021. That is, the orthographic projections of the source and drain layers 26 on substrate 1 are located in display area 101 and circuit area 1021. Each source and drain layer 26 is arranged corresponding to an active layer 21 and may include a source 261 and a drain 262 connected to two ends of the active layer 21.

In addition, the driving device layer 2 may further include a passivation layer. The passivation layer may cover the source and drain layer 26 and the interlayer dielectric layer 25, and the orthographic projection of the passivation layer on the substrate 1 at least covers the display area 101.

As shown in FIGS. 2 and 3, the planarization layer 100 is arranged on the side of the driving device layer 2 away from the substrate 1, and the boundary of the orthographic projection of the planarization layer 100 on the substrate 1 is located in the circuit area 1021. Meanwhile, the planarization layer 100 on the substrate 1 may be a single-layer structure or a multi-layer structure. For example, the planarization layer 100 may include a first planarization layer 3 and a second planarization layer 4.

The first planarization layer 3 covers the driving device layer 2, for example, covers the source and drain layer 26 and the interlayer dielectric layer 25, and the boundary of the orthographic projection of the first planarization layer 3 on the substrate 1 is located within the circuit area 1021, that is, the first planarization layer 3 only covers at least part of the entire display area 101 and the circuit area 1021.

On the surface of the first planarization layer 3 away from the substrate 1, a connection layer 10 and a signal line 11 may be arranged.

The connection layer 10 is arranged on the surface of the first planarization layer 3 away from the substrate 1, and the orthographic projection of the connection layer 10 on the substrate 1 is located in the display area 101. Meanwhile, the connection layer 10 is connected to the source and drain layer 26 through a via hole penetrating through the first planarization layer 3. The driving device layer 2 and the connection layer 10 may form a plurality of pixel circuits, and each pixel circuit may include a plurality of thin film transistors, capacitors and a part of the connection layer 10. The pixel circuit may be a pixel circuit such as 7T1C, 7T2C, 6T1C or 6T2C, and its structure is not specifically limited here. The nTmC indicates that a pixel circuit includes n transistors (indicated by the letter “T”) and m capacitors (indicated by the letter “C”).

The signal line 11 is arranged on a side of the blocking dam 6 close to the substrate 1. The signal line 11 includes a first line layer 111 and a second line layer 112 stacked in sequence in a direction away from the substrate 1. The first line layer 111 is arranged on the surface of the planarization layer 3 away from the substrate 1, and is at least partially located in the blocking area 1022. Of course, the first line layer 111 may also extend into the circuit area 1021. The first line layer 111 and the source and drain layer 26 are arranged in the same layer, so that the first line layer 111 and the source and drain layer 26 may be formed through the same patterning process. The second line layer 112 is arranged on the surface of the first line layer 111 away from the substrate 1, and the second line layer 112 and the connection layer 10 are arranged in the same layer, and thus the second line layer 112 and the connection layer 10 may be formed through the same patterning process.

As shown in FIG. 2 and FIG. 3, the second planarization layer 4 is arranged on the surface of the first planarization layer 3 away from the substrate 1 and covers the connection layer 10. The boundary of the orthographic projection of the second planarization layer 4 on the substrate 1 is located in the circuit area 1021, and this boundary is the boundary of the planarization layer 100, that is, the first boundary 001, and the boundary of the first planarization layer 3 is located within the first boundary 001.

As shown in FIG. 2 and FIG. 3, the light emitting layer 5 may be arranged on the surface of the second planarization layer 4 away from the substrate 1, and the orthographic projection of the light emitting layer 5 on the substrate 1 at least covers the display area 101. The light emitting layer 5 may include a plurality of light emitting devices, which may be organic light emitting devices (OLEDs), and each light emitting device may be connected to a pixel circuit. Each light emitting device may include a first electrode 511, a light emitting functional layer 53 and a second electrode stacked in a direction away from the substrate 1.

In some embodiments of the present disclosure, as shown in FIG. 2 and FIG. 3, the light emitting layer 5 includes a first electrode layer 51, a pixel definition layer 5 2, a light emitting functional layer 53 and a second electrode layer 54.

The first electrode layer 51 is arranged on a side of the second planarization layer 4 away from the substrate 1. For example, the first electrode layer 51 is directly arranged on the surface of the second planarization layer 4 away from the substrate 1. The first electrode layer 51 may include a first electrode 511 and an interconnection portion 512, and the first electrode 511 and the interconnection portion 512 may be formed simultaneously through the same patterning process. The orthographic projection of the first electrode 511 on the substrate 1 is located in display area 101, and the first electrode is used to form the anode of the light emitting device. There may be multiple first electrodes 511 and the first electrodes 511 are distributed in an array. The orthographic projection of the interconnection portion 512 on the substrate 1 is located in the circuit area 1021, and is not connected to a first electrode 511, that is, the first electrode 511 is disconnected from the interconnection portion 512. The pattern of the interconnection portion 512 is not specifically limited here. The interconnection portion 512 may be used to connect the second electrode to the signal line 11. Further, the interconnection portion 512 may be provided with a plurality of through holes for exhaust.

Further, as shown in FIG. 3, the first electrode layer 51 may further include an extension portion 513. The extension portion 513 is connected to the interconnection portion 512, and the orthographic projection of the extension portion 513 on the substrate 1 is located in the blocking area 1022. The extension portion 513 may be a film layer of the interconnection portion 512 extending continuously in a direction away from the first electrode 511, and the extension portion 513 is integrated with the interconnection portion 512 and the extension portion 513 and the interconnection portion 512 may be formed simultaneously through a single patterning process. Meanwhile, the extension portion 513 covers the signal line 11 and is electrically connected to the signal line 11.

The pixel definition layer 52 is arranged on the surface of the second planarization layer 4 away from the substrate 1, and the orthographic projection of the pixel definition layer 52 on the substrate 1 covers the display area 101 and the circuit area 1021. The pixel definition layer 52 is provided with at least one pixel opening 521 and an interconnection opening 522. The number of the at least one pixel opening 521 is the same as the number of the first electrodes 511, and pixel opening 521 exposes a first electrode in a one-to-one correspondence. The interconnection opening 522 exposes an interconnection portion 512, but the number of the interconnection portion(s) is not particularly limited.

The light emitting functional layer 53 covers the pixel definition layer 52 and the first electrode 511, and the orthographic projection of the light emitting functional layer 53 on the substrate 1 is located in the display area 101. For example, the light emitting functional layer 53 may include a hole injection layer, a hole transport layer, a light emitting material layer, an electron transport layer, and an electron injection layer which are stacked in sequence in a direction away from the substrate 1.

The second electrode layer 54 covers the light emitting functional layer 53, the boundary of the orthographic projection of the second electrode layer 54 on the substrate 1 is located in the circuit area 1021, and the second electrode layer 54 is connected to the interconnection portion 512 through the interconnection opening 522, so as to be connected to the signal line 11 through the interconnection portion 512. Meanwhile, the first electrode 511 may be connected to the connection layer 10 of a pixel circuit, so that a power signal may be input to the light emitting device through the signal line 11, and a driving signal may be input to a first electrode 511 through the peripheral circuit and the pixel circuit to drive the light emitting function layer 53 to emit light.

As shown in FIG. 2 and FIG. 3, the blocking dam 6 may be arranged on a side of the driving device layer 2 away from the substrate 1 and around the display area 101, and the orthographic projection of the blocking dam 6 on the substrate 1 is located in the blocking area 1022.

In some embodiments of the present disclosure, as shown in FIG. 2 and FIG. 3, the blocking dam 6 may include multiple concentrically spaced dam bodies, for example, it may include a first dam 61 and a second dam 62.

The first dam 61 is arranged in the same layer as the pixel definition layer 52, and is arranged on a surface of the extension portion 513 away from the substrate 1.

At least partial area of the second dam 62 is arranged on a surface of the signal line 11 away from the substrate 1. For example, a partial area of the second dam 62 is arranged on the surface of the second line layer 112 away from the substrate. The second dam 62 surrounds outside the first dam 61. The thickness of the second dam 62 may be greater than the thickness of the first dam 61. Further, the second dam 62 may include a first blocking layer 621 and a second blocking layer 622 which are stacked in a direction away from the substrate 1. The first blocking layer 621 and the second planarization layer 4 are arranged in the same layer, so that the first blocking layer 621 and the second planarization layer 4 may be formed through the same patterning process. The second blocking layer 622 and the pixel definition layer 52 are arranged in the same layer, and thus the second blocking layer 622 and the pixel definition layer 52 may be formed through the same patterning process.

The distance between the boundary of the second planarization layer 4 and the first dam 61 (that is, the minimum distance between the boundary of the second planarization layer 4 and a sidewall of the first dam 61 close to the second planarization layer 4) is the first distance L1.

The distance between the boundary of the second planarization layer 4 and the second dam 62 (that is, the minimum distance between the boundary of the second planarization layer 4 and a sidewall of the second dam 63 close to the second planarization layer 4) is the second distance L2.

The ratio of the second distance L2 to the first distance L1 may be 7/5, L2/L1=7/5. For example, the first distance is 200 μm, and the second distance may be 280 μm.

As shown in FIGS. 2 and 3, the first inorganic encapsulation layer 7 covers the light emitting layer 5 and the blocking dam 6, for example, covers the second electrode layer 54 and the blocking dam 6. The orthographic projection of the first inorganic encapsulation layer 7 on the substrate 1 covers the display area 101 and the peripheral area 102. The boundary of the first inorganic encapsulation layer 7 may be flush with the boundaries of the first gate insulating layer 22, the second gate insulating layer 24 and the interlayer dielectric layer 25. Since the boundary of the second planarization layer 4 is located in the circuit area 1021 and the boundary of the first inorganic encapsulation layer 7 is outside the second planarization layer 4, the first inorganic encapsulation layer 7 is depressed towards the substrate 1 at the sidewall of the second planarization layer 4 to reach the surface of the extension 513 away from the substrate 1.

As shown in FIG. 2 and FIG. 3, the organic encapsulation layer 8 is arranged on the surface of the first inorganic encapsulation layer 7 away from the substrate 1, and the orthographic projection of the organic encapsulation layer 8 on the substrate 1 is within the range surrounded by the blocking dam 6. For example, the organic encapsulation layer 8 is located within the range surrounded by the first dam 61. Meanwhile, the orthographic projection of the second planarization layer 4 on the substrate 1 is located within the orthographic projection of the organic encapsulation layer 8 on the substrate 1, so that the boundary of the second planarization layer 4 may be covered by the organic encapsulation layer 8 to achieve planarization.

As shown in FIG. 2 and FIG. 3, the second inorganic encapsulation layer 9 covers the organic encapsulation layer 8, and the orthographic projection of the second inorganic encapsulation layer 9 on the substrate 1 covers the display area 101 and the peripheral area 102, thereby covering the organic encapsulation layer 8 as between the first inorganic encapsulation layer 7 and the second inorganic encapsulation layer 9 to prevent external erosion.

In addition, in order to further prevent external erosion, the second planarization layer 4 may be provided with a first blocking groove 31 penetrating through the second planarization layer 4 and the first planarization layer 3, and the orthographic projection of the first blocking groove 31 on the substrate 1 is located in the circuit area 1021, and the first blocking groove 31 is an annular groove surrounding the display area 101. There may be multiple first blocking grooves 31, and the first blocking grooves 31 are concentrically spaced around the display area 101.

The interlayer dielectric layer 25 is provided with a second blocking groove 251 penetrating through the interlayer dielectric layer 25, and the orthographic projection of the second blocking groove 251 on the substrate 1 surrounds the blocking dam 6, for example, surrounds outside the second dam 62. There may be multiple second blocking grooves 251, and the second blocking grooves 251 are concentrically spaced around the blocking dam 6.

In addition, the display panel of the present disclosure may further include a touch layer arranged on the side of the second inorganic encapsulation layer 9 away from the substrate 1. The touch layer includes an electrode area and a wiring area located in the electrode area. The electrode area is provided with a touch electrode, and the wiring area is provided with traces connected to the touch electrode. The traces may be distributed along a direction away from the electrode area, and two adjacent traces are spaced to avoid short circuit. Among the traces, at least a partial area of a part of the traces is located outside the boundary of the second planarization layer 4, that is, a side away from the electrode area, and at least a partial area of another part of the traces is located inside the boundary. Since the planarization is achieved through the organic encapsulation layer 8, the structure in the present disclosure can avoid a situation that, when the touch layer is formed by a photolithography process, photoresist accumulates in the area corresponding to outside of the boundary of second planarization layer 4, the exposure of the photoresist cannot be sufficient, and in the area where the exposure of the photoresist is not sufficient, the photoresist cannot be removed after development, and thus the material in this area cannot be etched, and as a result two adjacent traces outside the boundary cannot be separated in this area, resulting in a short circuit and affecting the touch function.

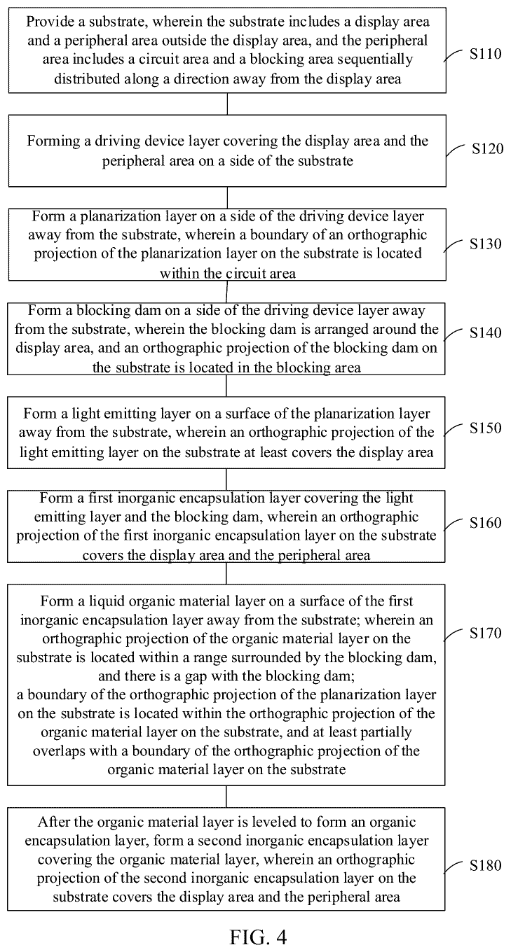

An embodiment of the present disclosure provides a method for manufacturing a display panel. The display panel is the display panel of any of the above embodiments. As shown in FIG. 4, the manufacturing method may include step S110-step S190.

In step S110, a substrate is provided. The substrate includes a display area and a peripheral area outside the display area. The peripheral area includes a circuit area and a blocking area distributed in sequence along a direction away from the display area.

In step S120, a driving device layer covering the display area and the peripheral area is formed on a side of the substrate.

In step S130, a planarization layer is formed on a side of the driving device layer away from the substrate. The boundary of the orthographic projection of the planarization layer on the substrate is located within the circuit area.

In step S140, a blocking dam is formed on a side of the driving device layer away from the substrate. The blocking dam is arranged around the display area. The orthographic projection of the blocking dam on the substrate is located on the blocking area.

In step S150, a light emitting layer is formed on a surface of the planarization layer away from the substrate. The orthographic projection of the light emitting layer on the substrate at least covers the display area.

In step S160, a first inorganic encapsulation layer covering the light emitting layer and the blocking dam is formed. The orthographic projection of the first inorganic encapsulation layer on the substrate covers the display area and the peripheral area.

In step S170, a liquid organic material layer is formed on the surface of the first inorganic encapsulation layer away from the substrate. The orthographic projection of the organic material layer on the substrate is within the range surrounded by the blocking dam, and there is a gap between the organic material layer and the blocking dam. The boundary of the orthographic projection of the planarization layer on the substrate is located within the orthographic projection of the organic material layer on the substrate, and at least partially overlaps with a boundary of the orthographic projection of the organic material layer on the substrate.

In step S180, after the organic material layer is leveled to form an organic encapsulation layer, a second inorganic encapsulation layer covering the organic material layer is formed. The orthographic projection of the second inorganic encapsulation layer on the substrate covers the display area and the peripheral area.

Further, in some embodiments of the present disclosure, a planarization layer is formed on a side of the driving device layer away from the substrate, and the boundary of the orthographic projection of the planarization layer on the substrate is located in the circuit area; that is, step S130 may include the following steps 1 and 2:

In step 1, a first planarization layer covering the driving device layer is formed. A boundary of an orthographic projection of the first planarization layer on the substrate is located in the circuit area.

In step 2, a second planarization layer is formed on a side of the first planarization layer away from the substrate. A boundary of an orthographic projection of the second planarization layer on the substrate is located in the circuit area.

The light emitting layer is arranged on the surface of the second planarization layer away from the substrate.

Further, the organic encapsulation layer 8 may be formed by an inkjet printing process. Specifically, an inkjet printing device may be used to print a liquid organic material layer on the first inorganic encapsulation layer 7, and the boundary of the organic material layer is the printing boundary set by the inkjet printing device. After the organic material diffuses outwards, and the boundary gradually expands to leveling, an organic encapsulation layer 8 is formed. The boundary of the second planarization layer 4 is located within the boundary for printing the organic material layer, and in the direction perpendicular to the substrate 1, the boundary of the second planarization layer 4 at least partially overlaps with the boundary of the organic material layer, ensuring that the boundary of the second planarization layer 4 can be covered while avoiding too much printed organic material. If too much organic material is printed, the organic material may be too close to the blocking dam and the organic material may run over the blocking dam 6 after leveling, resulting in package failure. For example, the thickness of the first dam 61 is not greater than 2 μm, and the thickness of the organic material layer is not less than 8 μm.

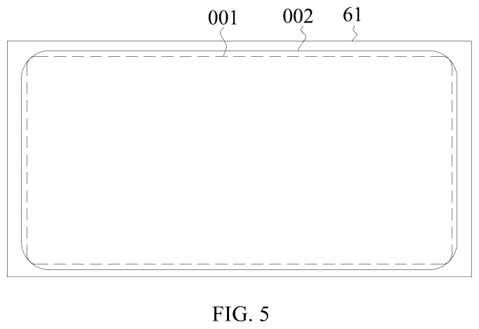

In some embodiments of the present disclosure, each of the orthographic projections of the second planarization layer and the organic material layer on the substrate is a rectangle, and two adjacent sides of the rectangle are connected through a rounded corner. The four sides of the orthographic projection of the second planarization layer on the substrate are located outside the orthographic projection of the organic material layer on the substrate, and the rounded corner of the orthographic projection of the second planarization layer on the substrate is inscribed in the rounded corner of the orthographic projection of the organic material layer on the substrate. As shown in FIG. 5, the first boundary 001 is the boundary of the second planarization layer 4, and the second boundary 002 is the boundary of the organic material layer.

In some embodiments of the present disclosure, a light emitting layer is formed on the surface of the second planarization layer away from the substrate; that is, step S160 includes the following steps 1-4.

In step 1, a first electrode layer is formed on the side of the second planarization layer away from the substrate. The first electrode layer includes a first electrode and an interconnection portion, an orthographic projection of the first electrode on the substrate is located in the display area, and an orthographic projection of the interconnection portion on the substrate is located in the circuit area.

In step 2, a pixel definition layer is formed on the surface of the second planarization layer away from the substrate. An orthographic projection of the pixel definition layer on the substrate covers the display area and the circuit area, and the pixel definition layer is provided with a pixel opening exposing the first electrode and an interconnection opening exposing the interconnection portion.

In step 3, a light emitting functional layer covering the pixel definition layer and the first electrode is formed. An orthographic projection of the light emitting functional layer on the substrate is located in the display area.

In step 4, a second electrode layer covering the light emitting functional layer is formed. The boundary of the orthographic projection of the second electrode layer on the substrate is located in the circuit area, and the second electrode is connected to the interconnection portion through the interconnection opening.

The blocking dam includes a first dam and a second dam, and for the specific structure, reference may be made to the above embodiments of the display panel. The first blocking layer and the second planarization layer are simultaneously formed through one patterning process, and the second blocking layer, the first dam and the pixel definition layer are formed simultaneously through one patterning process.

It should be noted that although various steps of the manufacturing method in the present disclosure are described in a specific order in the drawings, this does not require or imply that these steps must be performed in this specific order, or that all shown steps must be performed to achieve the desired result. Additionally or alternatively, certain steps may be omitted, multiple steps may be combined into one step for execution, and/or one step may be decomposed into multiple steps for execution, etc.

An embodiment of the present disclosure also provides a display device, which may include the display panel in any of the above embodiments. For the structure and beneficial effects of the display panel, reference may be made to the above embodiments of the display panel, which will not be repeated here. The display device of the present disclosure may be an electronic device such as a mobile phone, a tablet computer, a notebook computer, etc., and will not be listed here.

Other embodiments of the present disclosure will be readily apparent to those skilled in the art from consideration of the specification and practice of the invention disclosed herein. The present disclosure is intended to cover any modification, use or adaptation of the present disclosure, and these modifications, uses or adaptations follow the general principles of the present disclosure and include common knowledge or conventional technical means in the technical field which is not disclosed in the present disclosure. The specification and examples are to be considered exemplary only, with the true scope and spirit of the present disclosure indicated by the appended claims.

1. A display panel, comprising:
a substrate comprising a display area and a peripheral area outside the display area, wherein the peripheral area comprises a circuit area and a blocking area sequentially distributed along a direction away from the display area;
a driving device layer arranged on a side of the substrate and covering the display area and the peripheral area;
a planarization layer arranged on a side of the driving device layer away from the substrate, wherein a boundary of an orthographic projection of the planarization layer on the substrate is located within the circuit area;
a light emitting layer arranged on a surface of the planarization layer away from the substrate, wherein an orthographic projection of the light emitting layer on the substrate at least covers the display area;
a blocking dam arranged on a side of the driving device layer away from the substrate and arranged around the display area, wherein an orthographic projection of the blocking dam on the substrate is located in the blocking area;
a first inorganic encapsulation layer covering the light emitting layer and the blocking dam, wherein an orthographic projection of the first inorganic encapsulation layer on the substrate covers the display area and the peripheral area;
an organic encapsulation layer arranged on a surface of the first inorganic encapsulation layer away from the substrate, wherein an orthographic projection of the planarization layer on the substrate is located within an orthographic projection of the organic encapsulation layer on the substrate; and
a second inorganic encapsulation layer covering the organic encapsulation layer, wherein an orthographic projection of the second inorganic encapsulation layer on the substrate covers the display area and the peripheral area.

2. The display panel according to claim 1, wherein the planarization layer comprises:
a first planarization layer covering the driving device layer, wherein a boundary of an orthographic projection of the first planarization layer on the substrate is located within the circuit area; and
a second planarization layer arranged on a side of the first planarization layer away from the substrate, wherein a boundary of an orthographic projection of the second planarization layer on the substrate is located within the circuit area, and the light emitting layer is arranged on a surface of the second planarization layer away from the substrate.

3. The display panel according to claim 2, wherein the light emitting layer comprises:
a first electrode layer arranged on the side of the second planarization layer away from the substrate, wherein the first electrode layer comprises a first electrode and an interconnection portion, an orthographic projection of the first electrode on the substrate is located in the display area, and an orthographic projection of the interconnection portion on the substrate is located in the circuit area;
a pixel definition layer arranged on a surface of the second planarization layer away from the substrate, wherein an orthographic projection of the pixel definition layer on the substrate covers the display area and the circuit area, and the pixel definition layer is provided with a pixel opening exposing the first electrode and an interconnection opening exposing the interconnection portion;
a light emitting functional layer covering the pixel definition layer and the first electrode, wherein an orthographic projection of the light emitting functional layer on the substrate is located in the display area; and
a second electrode layer covering the light emitting functional layer, wherein a boundary of an orthographic projection of the second electrode layer on the substrate is located in the circuit area, and the second electrode layer is connected to the interconnection portion through the interconnection opening;
wherein the first inorganic encapsulation layer covers the second electrode layer.

4. The display panel according to claim 3, wherein the blocking dam comprises a first dam and a second dam, and the second dam surrounds the first dam.

5. The display panel according to claim 4, wherein the first dam is arranged in the same layer as the pixel definition layer, the second dam comprises a first blocking layer and a second blocking layer stacked in a direction away from the substrate, the first blocking layer is arranged in the same layer as the second planarization layer, and the second blocking layer is arranged in the same layer as the pixel definition layer.

6. The display panel according to claim 5, wherein the first electrode layer further comprises:
an extension portion connected to the interconnection portion, wherein an orthographic projection of the extension portion on the substrate is located in the blocking area;
wherein the first dam is arranged on a surface of the extension portion away from the substrate.

7. The display panel according to claim 6, wherein the driving device layer comprises:
an active layer arranged on a side of the substrate, wherein an orthographic projection of the active layer on the substrate is located in the display area and the circuit area;
a first gate insulating layer covering the active layer and the substrate;
a gate arranged on a surface of the first gate insulating layer away from the substrate, wherein an orthographic projection of the gate on the substrate is located in the display area and the circuit area;
a second gate insulating layer covering the gate and the first gate insulating layer;
an interlayer dielectric layer covering the second gate insulating layer;
an source and drain layer arranged on a surface of the interlayer dielectric layer away from the substrate, wherein an orthographic projection of the source and drain layer on the substrate is located in the display area and the circuit area; and
the first planarization layer arranged on a side of the source and drain layer away from the substrate;
wherein the display panel further comprises:
a connection layer arranged on a surface of the first planarization layer away from the substrate and connected to the source and drain layer, wherein an orthographic projection of the connection layer on the substrate is located in the display area;
a signal line arranged on a side of the blocking dam close to the substrate, wherein the signal line comprises a first line layer and a second line layer stacked sequentially in a direction away from the substrate, the first line layer is arranged in the same layer as the source and drain layer, the second line layer is arranged in the same layer as the connection layer, and at least a partial area of the second dam is arranged on a surface of the second line layer away from the substrate;
wherein the extension portion is arranged on a surface of the signal line away from the substrate.

8. The display panel according to claim 3, wherein the second planarization layer is provided with a first blocking groove penetrating through the second planarization layer and the first planarization layer, and an orthographic projection of the first blocking groove on the substrate is located in the circuit area and surrounds the display area.

9. The display panel according to claim 7, wherein the interlayer dielectric layer is provided with a second blocking groove, and an orthographic projection of the second blocking groove on the substrate surrounds the second dam.

10. The display panel according to claim 4, wherein:
a distance between a boundary of the second planarization layer and the first dam is a first distance, and a distance between a boundary of the second planarization layer and the second dam is a second distance; and
a ratio of the second distance to the first distance is 7/5.

11. A method for manufacturing a display panel, comprising:
providing a substrate, wherein the substrate comprises a display area and a peripheral area outside the display area, and the peripheral area comprises a circuit area and a blocking area sequentially distributed along a direction away from the display area;
forming a driving device layer covering the display area and the peripheral area on a side of the substrate;
forming a planarization layer on a side of the driving device layer away from the substrate, wherein a boundary of an orthographic projection of the planarization layer on the substrate is located within the circuit area;
forming a blocking dam on a side of the driving device layer away from the substrate, wherein the blocking dam is arranged around the display area, and an orthographic projection of the blocking dam on the substrate is located in the blocking area;
forming a light emitting layer on a surface of the planarization layer away from the substrate, wherein an orthographic projection of the light emitting layer on the substrate at least covers the display area;
forming a first inorganic encapsulation layer covering the light emitting layer and the blocking dam, wherein an orthographic projection of the first inorganic encapsulation layer on the substrate covers the display area and the peripheral area;
forming a liquid organic material layer on a surface of the first inorganic encapsulation layer away from the substrate, wherein:
an orthographic projection of the organic material layer on the substrate is located within a range surrounded by the blocking dam, and there is a gap between the organic material layer and the blocking dam;
a boundary of the orthographic projection of the planarization layer on the substrate is located within the orthographic projection of the organic material layer on the substrate, and at least partially overlaps with a boundary of the orthographic projection of the organic material layer on the substrate;
after the organic material layer is leveled to form an organic encapsulation layer, forming a second inorganic encapsulation layer covering the organic material layer, wherein an orthographic projection of the second inorganic encapsulation layer on the substrate covers the display area and the peripheral area.

12. The manufacturing method according to claim 11, wherein forming the planarization layer on the side of the driving device layer away from the substrate comprises:
forming a first planarization layer covering the driving device layer, wherein a boundary of an orthographic projection of the first planarization layer on the substrate is located in the circuit area; and
forming a second planarization layer on a side of the first planarization layer away from the substrate, wherein a boundary of an orthographic projection of the second planarization layer on the substrate is located in the circuit area;
wherein the light emitting layer is arranged on a surface of the second planarization layer away from the substrate.

13. The manufacturing method according to claim 12, wherein each of the orthographic projections of the second planarization layer and the organic material layer on the substrate is a rectangle, and two adjacent sides of the rectangle are connected through a rounded corner;
a rounded corner of the orthographic projection of the second planarization layer on the substrate is inscribed in a rounded corner of the orthographic projection of the organic material layer on the substrate.

14. The manufacturing method according to claim 12, wherein forming the light emitting layer on the surface of the second planarization layer away from the substrate; comprising:
forming a first electrode layer on a side of the second planarization layer away from the substrate, wherein the first electrode layer comprises a first electrode and an interconnection portion, an orthographic projection of the first electrode on the substrate is located in the display area, and an orthographic projection of the interconnection portion on the substrate is located in the circuit area;
forming a pixel definition layer on the surface of the second planarization layer away from the substrate, wherein an orthographic projection of the pixel definition layer on the substrate covers the display area and the circuit area, and the pixel definition layer is provided with a pixel opening exposing the first electrode and an interconnection opening exposing the interconnection portion;
forming a light emitting functional layer covering the pixel definition layer and the first electrode, wherein an orthographic projection of the light emitting functional layer on the substrate is located within the display area;
forming a second electrode layer covering the light emitting functional layer, wherein a boundary of an orthographic projection of the second electrode layer on the substrate is located in the circuit area, and the second electrode layer is connected to the interconnection portion through the interconnection opening;
wherein:
the blocking dam comprises a first dam and a second dam, and the second dam surrounds the first dam;
the second dam comprises a first blocking layer and a second blocking layer stacked in a direction away from the substrate, the first blocking layer and the second planarization layer are provided simultaneously through one patterning process, and the second blocking layer, the first dam and the pixel definition layer are simultaneously formed through one patterning process.

15. The manufacturing method according to claim 14, wherein a thickness of the first dam is not greater than 2 μm, and a thickness of the organic material layer is not less than 8 μm.

16. A display device, comprising a display panel,
wherein the display panel comprises:
a substrate comprising a display area and a peripheral area outside the display area, wherein the peripheral area comprises a circuit area and a blocking area sequentially distributed along a direction away from the display area;
a driving device layer arranged on a side of the substrate and covering the display area and the peripheral area;
a planarization layer arranged on a side of the driving device layer away from the substrate, wherein a boundary of an orthographic projection of the planarization layer on the substrate is located within the circuit area;
a light emitting layer arranged on a surface of the planarization layer away from the substrate, wherein an orthographic projection of the light emitting layer on the substrate at least covers the display area;
a blocking dam arranged on a side of the driving device layer away from the substrate and arranged around the display area, wherein an orthographic projection of the blocking dam on the substrate is located in the blocking area;
a first inorganic encapsulation layer covering the light emitting layer and the blocking dam, wherein an orthographic projection of the first inorganic encapsulation layer on the substrate covers the display area and the peripheral area;
an organic encapsulation layer arranged on a surface of the first inorganic encapsulation layer away from the substrate, wherein an orthographic projection of the planarization layer on the substrate is located within an orthographic projection of the organic encapsulation layer on the substrate; and
a second inorganic encapsulation layer covering the organic encapsulation layer, wherein an orthographic projection of the second inorganic encapsulation layer on the substrate covers the display area and the peripheral area.

17. The display device according to claim 16, wherein the planarization layer comprises:
a first planarization layer covering the driving device layer, wherein a boundary of an orthographic projection of the first planarization layer on the substrate is located within the circuit area; and
a second planarization layer arranged on a side of the first planarization layer away from the substrate, wherein a boundary of an orthographic projection of the second planarization layer on the substrate is located within the circuit area, and the light emitting layer is arranged on a surface of the second planarization layer away from the substrate.

18. The display device according to claim 17, wherein the light emitting layer comprises:
a first electrode layer arranged on the side of the second planarization layer away from the substrate, wherein the first electrode layer comprises a first electrode and an interconnection portion, an orthographic projection of the first electrode on the substrate is located in the display area, and an orthographic projection of the interconnection portion on the substrate is located in the circuit area;
a pixel definition layer arranged on a surface of the second planarization layer away from the substrate, wherein an orthographic projection of the pixel definition layer on the substrate covers the display area and the circuit area, and the pixel definition layer is provided with a pixel opening exposing the first electrode and an interconnection opening exposing the interconnection portion;
a light emitting functional layer covering the pixel definition layer and the first electrode, wherein an orthographic projection of the light emitting functional layer on the substrate is located in the display area; and
a second electrode layer covering the light emitting functional layer, wherein a boundary of an orthographic projection of the second electrode layer on the substrate is located in the circuit area, and the second electrode layer is connected to the interconnection portion through the interconnection opening;
wherein the first inorganic encapsulation layer covers the second electrode layer.

19. The display device according to claim 18, wherein the blocking dam comprises a first dam and a second dam, and the second dam surrounds the first dam.

20. The method according to claim 12, wherein the liquid organic material layer is formed by an inkjet printing process, and a boundary of the second planarization is located within a boundary for printing the organic material layer.
